(19) United States
(12) Patent Application Publication
(10) Pub. No.: US 2026/0290715 A1
(43) Pub. Date: Sep. 24, 2026

(54) MEMS BRIDGE

(71) Applicant: SOFANT TECHNOLOGIES LTD, Edinburgh (GB)

(72) Inventor: Thomas Harry HANLEY, Edinburgh (GB)

(73) Assignee: SOFANT TECHNOLOGIES LTD, Edinburgh (GB)

(21) Appl. No.: 19/472,315

(22) PCT Filed: Apr. 4, 2024
(86) PCT No.: PCT/GB2024/050913

§ 371 Date: Oct. 3, 2025

(30) Foreign Application Priority Data
Apr. 4, 2023 (GB) 2305031.3

(51) Int. Cl. H01H 1/00; B81B 3/00; B81C 1/00

(52) U.S. Cl. CPC H01H 1/0036; B81B 3/0072; B81C 1/00666; B81B 2201/016; B81B 2203/0109; B81B 2203/0307

(57) ABSTRACT

The present invention provides a radio frequency, RF, microelectromechanical systems, MEMS, switch comprising: a substrate; a first signal conductor on the substrate; ground conductors supported on either side of the first signal conductor on the substrate; and a MEMS bridge at least one end of which is mechanically connected to the substrate by way of at least one anchor, the MEMS bridge comprising a variable capacitor region provided over the first signal conductor, the variable capacitor region comprising a first dielectric layer and a first conductive layer, the first conductive layer positioned on a surface of the first dielectric layer facing the substrate and separated into at least a first longitudinal conductive portion and a second longitudinal conductive portion which are spaced apart in a direction perpendicular to the longitudinal length of the MEMS bridge, wherein the substrate comprises one or more pull-down substrate conductors and the MEMS bridge comprises one or more actuatable conductors located between the anchors and the variable capacitor region and provided above the one or more pull-down substrate conductors, wherein at least one of the one or more actuatable conductors comprises an embedded portion which extends longitudinally along the MEMS bridge and between the first and second longitudinal conductive portions.

### FIELD OF THE INVENTION

The invention relates to radio frequency (RF) microelectromechanical systems (MEMS) switches, including a variable capacitor region, and methods of manufacturing an RF MEMS switch.

### BACKGROUND TO THE INVENTION

Radio frequency (RF) microelectromechanical systems (MEMS) switches typically comprise a signal conductor supported by a substrate and a bridge extending over the signal conductor, the bridge being movable between an up state and a down state to change one or more electrical properties, such as the capacitance or resistance, of the switch. The application focuses on capacitive switches in which the up and down state of the bridge have different capacitances rather than on/off or open/closed switches.

U.S. Pat. No. 7,126,447B2 discloses an RF-MEMS switch including a plurality of movable electrodes disposed with a space provided therebetween in the direction of RF signal conduction of an RF signal-conducting unit which is provided above the RF signal-conducting unit.

It is desirable to obtain a high and well-controlled change in capacitance between the up state and the down state. In order to obtain a high ratio of capacitance between the up state and the down state, the gap distance between the bridge and the substrate when the bridge is in the down state should be minimised. Furthermore, the gap distances should ideally be predictable and consistent.

It is in this context that the present disclosure has been devised.

### SUMMARY OF THE INVENTION

Within this specification and the appended claims, by a MEMS switch we refer to a MEMS device which is switchable between at least a first state and a second state thereby changing at least one impedance (typically capacitance and/or resistance). In some embodiments, the MEMS device is a capacitive MEMS switch. In the present invention, the MEMS switch comprises a signal line support on a substrate and a MEMS bridge, which is moveable relative to the signal line between the first and second states, thereby changing at least one capacitance and/or resistance.

According to a first aspect of the present invention, there is provided a radio frequency, RF, microelectromechanical systems, MEMS, switch comprising: a substrate; at least one signal conductor supported on the substrate; and a MEMS bridge at least one end of which is mechanically connected to the substrate by way of at least one anchor. The MEMS bridge comprises a variable capacitor region provided over the at least one signal conductor. The variable capacitor region comprises a first dielectric layer and a first conductive layer. The first conductive layer is positioned on a surface of the first dielectric layer facing the substrate and separated into at least a first longitudinal conductive portion and a second longitudinal conductive portion. The first and second longitudinal conductive portions are spaced apart in a direction perpendicular to the longitudinal length of the MEMS bridge.

According to a second aspect of the present invention, there is provided a method of manufacturing a radio frequency, RF, microelectromechanical systems, MEMS, switch as described below. The method comprises: providing a substrate; and providing at least one signal conductor supported by the substrate. The method comprises: providing a MEMS bridge comprising a variable capacitor region over the at least one signal conductor by providing a first dielectric layer and a first conductive layer. The first conductive layer is provided on the surface of the first dielectric layer facing the substrate and separated into at least a first longitudinal conductive portion and a second longitudinal conductive portion. The first and second longitudinal conductive portions are spaced apart in a direction perpendicular to the longitudinal length of the MEMS bridge.

It may be that the at least one signal conductor comprises a first signal conductor and a second signal conductor. It may be that the first and second signal conductors are a part of the same signal line which is split. It may be that this is a series configuration of the RF MEMS switch.

It may be that the MEMS switch comprises a first signal conductor and ground conductors supported on the substrate on either side of the first signal conductor. It may be that the variable capacitor region is provided over the ground conductors. It may be that this is a shunt configuration of the RF MEMS switch.

Typically, the substrate comprises a first surface upon which the at least one signal conductor, ground conductors and MEMS bridge are supported. The substrate is typically formed of a material with a high-resistivity, for example a high resistivity undoped silicon. The signal conductor and the ground conductors are typically made of a conductive material, typically metallic, for example aluminium, gold, molybdenum, copper, titanium, nickel, platinum, chromium or aluminium alloys such as Al-Cu, Al-Si and Al-Nd.

By the variable capacitor region being provided over the at least one signal conductor(and the ground conductors), we refer to the direction away from the substrate in which the at least one signal conductor (and ground conductors) is formed, irrespective of the orientation of the device.

The signal conductor and the ground conductors on either side of the signal conductor typically form a co-planar waveguide on the substrate for guiding signals along the signal conductor.

It may be that the MEMS bridge is deformable from a first position in which the variable capacitor portion is spaced from the respective at least one signal (and ground) conductor(s) to a second position in which the variable capacitor region is closer to the respective at least one signal conductor than in the first position by way of an electrostatic actuation force. It may be that the capacitances between the variable capacitance region and the at least one signal conductor (and the ground conductors) are greater when the MEMS bridge is in the second position than when the MEMS bridge is in the first position.

In the shunt configuration, a capacitor may be formed between the MEMS bridge and each of the ground conductors and the signal conductor. In the series configuration, a capacitor may be formed between the MEMS bridge and each of the signal conductors.

The first position may be an up state of the MEMS bridge. The second position may be a down state of the MEMS bridge. By the first or up state of the MEMS bridge, switch or device we refer to a state in which the MEMS bridge is spaced apart from the substrate, at least over the signal conductor, and by the second or down state we refer to a state in which the MEMS bridge is in contact with the substrate (typically through intervening layers).

Typically, the variable capacitor region is moveable from a first position to a second position, e.g. in first and second positions of the MEMS bridge. Typically, in the second position, the variable capacitor region is closer to the substrate than in the first position. Typically, in the second position, the variable capacitor region is closer to the signal conductor (and the ground conductor(s)) than in the first position. Typically, in the second position, a portion of the MEMS bridge is closer to the substrate than when the MEMS bridge is in the first position. Typically, in the second position, a portion of the MEMS bridge is closer to the signal conductor (and ground conductor(s)) than when the MEMS bridge is in the first position. Typically, the anchor(s) do not move when the MEMS bridge moves from its first position to its second position.

Typical bilayer MEMS bridges comprise a different material for each layer. The different materials may have different stress properties. The difference in stress properties may result in a high stress differential between the bridge layers. For example, the layers may be made of materials with different thermal expansion coefficients which causes curvature and bowing of the bridge when exposed to high temperatures. When the MEMS bridge is actuated, the bridge may experience transverse warping due to torque imposed by the layer with a higher stress parameter on the layer with the lower stress parameter. The stress may be introduced to the bridge during deposition or further downstream processes which occur at higher temperatures.

A problem associated with transverse warp is that the ratio in capacitance between the MEMS bridge in its up state compared to its down state is smaller when the MEMS bridge is transversely warped compared to the change in capacitance between the MEMS bridge in its up state compared to its down state when the MEMS bridge is flat. This is because contact between the bridge and the signal conductor and ground conductors (which may be via an intervening layer) is reduced, and an air gap is introduced between the substrate and the MEMS bridge.

Advantageously, by providing the first conductive layer in spaced apart and separate first and second longitudinal conductive portions, the torque applied to the bridge can be controlled. By providing spaced apart and separate longitudinal conductive portions, the torque can be controlled so the MEMS bridge experience less warping and may be substantially flat when in the down state. In particular, the torque exerted by the first conductive layer on the first dielectric layer can be controlled. At parts of the MEMS bridge in which the first conductive layer is provided, a torque is exerted on the first dielectric layer. Therefore, when the first conductive layer is distributed by having the first and second separate longitudinal conductive portions, a distributed torque is realised in the bridge. The parts of the bridge in which there is no first conductive layer (i.e. the parts of the bridge which are formed of the first dielectric layer and are located between longitudinal conductive portions and the MEMS bridge centre-line) have a bulk modulus which acts to resist the torque exerted by the longitudinal conductive portions. Therefore, by placing longitudinal conductive portions spaced apart laterally across the MEMS bridge, the effect of this distributed torque on the warping of the MEMS bridge is minimised for a given area of the first conductive layer on the MEMS bridge.

In general, it is desirable to achieve a large change in capacitance between the up state and the down state of the MEMS bridge without increasing the overall size of the MEMS device. The present invention allows the change in capacitance per unit area of the MEMS bridge between the up state to the down state to be higher than a MEMS bridge without the first and second longitudinal conductive portions. The change in capacitance per unit area of the MEMS bridge between the up state to the down state may be referred to as the ratio of capacitance (e.g. between the up state and the down state).

It may be that the ratio of stress between the first conductive layer and the first dielectric layer is greater than 1:1 when the MEMS bridge is in the second position.

Typically, the capacitance of the MEMS bridge changes between the up and down states, for example by a factor of at least 5 or at least 10 or at least 100 or at least 1000. Typically, the RF MEMS switch is a capacitive switch. The MEMS switch may be a shunt or series capacitive switch. The MEMS switch may be used in a phase shifter (wherein the change in impedance (in particular capacitance) between up and down states leads to a change in the phase of a signal in the signal conductor).

It may be that the RF MEMS switch is configured for use with RF signals with a frequency greater than 10 GHz. It may be that the RF MEMS switch is configured for use with RF signals with a frequency greater than 15 GHz, greater than 20 GHz.

It may be that the MEMS bridge is cantilevered, having one end which is mechanically connected to the substrate by way one anchor. It may be that the MEMS bridge has opposing first and second ends which are connected to the substrate by respective anchors. It may be that the RF MEMS switch is a teeter-totter switch wherein the MEMS bridge is mechanically connected to the substrate through one anchor functioning as a pivot.

Typically, the MEMS bridge is formed of a spanning portion. The spanning portion may span the signal conductor (and the ground conductors). The spanning portion may be vertically separated from the substrate by an air gap when the MEMS bridge is in the up state. The spanning portion may be closer to the substrate when the MEMS bridge is in the down state than the up state. The spanning portion may comprise the variable capacitor region. The spanning portion may contact the substrate when the MEMS bridge is in the down state. The spanning portion may typically be the variable capacitor region. The spanning portion may typically connected to the one or more anchors.

Optionally, the MEMS bridge may be cantilevered in that the MEMS bridge has one anchor mechanically connecting the spanning portion of the MEMS bridge to the substrate. Optionally, the MEMS bridge (i.e. the spanning portion) may be supported by an anchor at opposing ends of the MEMS bridge. The first end may be mechanically connected to the substrate and supported by a first anchor and the second end may be mechanically connected to the substrate and supported by a second anchor. The first and second ends are typically edges of the MEMS bridge perpendicular to the longitudinal edges of the MEMS bridge. Typically, when the RF MEMS switch is a teeter-totter switch, the MEMS bridge is mechanically connected to the substrate through a pivot, which typically also functions as the anchor or to which the anchor may be connected. Optionally, a teeter-totter switch may comprise a first and second signal conductor on either side of the anchor (i.e. pivot), optionally with respective ground conductors on either side of each signal conductor.

Throughout the application, the term longitudinal (e.g. edge) is intended to refer to the direction in which the longest length (e.g. edge) extends. The term lateral (e.g. edge) is intended to refer to a direction perpendicular to the longitudinal length (e.g. edge) and is the second longest length (e.g. edge). The MEMS bridge (e.g. variable capacitor region) is typically connected to an anchor along its lateral edge and is exposed along its longitudinal edge.

The variable capacitor region may typically comprise a variable capacitor. The variable capacitor region may typically comprise a voltage-controlled variable capacitor (e.g. a MEMS varactor). A MEMS varactor typically provides two or more states having two or more capacitances. The variable capacitor region may function as a phase shifter by applying a phase shift to signals passing along the signal conductor (e.g. a shunt configuration) or as a switch to make/break connection between two, usually disconnected, signal tracks in a co-planar waveguide (e.g. a series configuration).

Typically, in some examples, the variable capacitor region refers to a portion of the MEMS bridge, which may be the spanning portion, which forms capacitive connections with the signal conductor and ground conductors. Typically, in some examples, the variable capacitor region refers to a portion of the MEMS bridge, which may be the spanning portion, which forms capacitive connections with the signal conductors.

The variable capacitor region is typically formed of two layers: the first conductive layer and the first dielectric layer. The first conductive layer is typically formed of a conductive material, typically metallic, for example aluminium, gold, molybdenum, copper, titanium, nickel, platinum, chromium or aluminium alloys such as Al-Cu, Al-Si and Al-Nd. The first dielectric layer is typically formed of an electrically insulating material (e.g. silicon nitride, strontium-titanate-oxide (SrTiO₃), parylene, polyimide, aluminium oxide, aluminium nitride, silicon dioxide, hafnia, zirconia, etc.). The first dielectric layer is typically above, in the direction away from the substrate, the first conductive layer.

The MEMS bridge typically comprises an upper surface facing away from the substrate and a lower surface facing towards the substrate. It may be that the lower surface is formed of both the first conductive layer and the second conductive layer. The MEMS bridge may comprise longitudinal edges of at least 100 microns, at least 200 microns, at least 300 microns, at least 400 microns, at least 450 microns or at least 500 microns. The MEMS bridge may comprise lateral edges of at least 10 microns, at least 20 microns, at least 30 microns, at least 35 microns, at least 40 microns, at least 45 microns or at least 50 microns. The MEMS bridge may have a thickness, in the direction extending perpendicular to the substrate, of at least 0.5 microns, at least 1 micron, at least 1.5 microns or at least 2 microns.

The first and second longitudinal conductive portions typically each contact the at least one signal conductor (and the ground conductors) when the MEMS bridge is in the second position.

The first and second longitudinal conductive portions are typically part of the first conductive layer. The first and second longitudinal conductive portions typically have a significantly longer longitudinal edge than their lateral edge. The first and second conductive portions may have the same length as the longitudinal length of the variable capacitor region or may have a length shorter than the longitudinal length of the variable capacitor region.

Optionally, the first and second longitudinal conductive portions may be separated by a portion of the first dielectric layer. That is, the first and second longitudinal conductive portions may be integrated into the first dielectric layer. The first and second longitudinal conductive portions are separated in the direction of the lateral edge of the variable capacitor region.

It may be that the first and second longitudinal conductive portions extend along opposing longitudinal edges of the variable capacitor region parallel to the longitudinal length of the MEMS bridge. It may be that the method of providing the first conductive layer comprises providing the first and second longitudinal conductive portions extending along opposing longitudinal edges of the variable capacitor region parallel to the longitudinal length of the MEMS bridge.

Advantageously, providing the first and second longitudinal conductive portions along the longitudinal edges of the variable capacitor region reduce the curvature of the MEMS bridge when the MEMS bridge is actuated towards the substrate. Both conductive portions cause torque which is distributed across the MEMS bridge. However, the portions of the MEMS bridge which do not have the first conductive portion, resist the bending caused by the torque of the conductive portions. By positioning the conductive portions at the longitudinal edges of the MEMS bridge, the desired ratio of capacitance between the up state and the down state is able to be achieved whilst also having a central portion without the first conductive layer that resists the bending caused by the torque. This allows the MEMS bridge to function as a variable capacitor whilst also optimising the ratio of capacitance between the up state and the down state achieved by reducing the curvature.

The first and second longitudinal conductive portions are typically aligned with the longitudinal edges of the variable capacitor region. It may be that the method comprises forming the first and second longitudinal conductive portions aligned with the longitudinal edges of the variable capacitor region. The first and second longitudinal conductive portions are typically aligned with the longitudinal edges of the MEMS bridge (e.g. the spanning portion). It may be that the method comprises forming the first and second longitudinal conductive portions aligned with the longitudinal edges of the MEMS bridge (e.g. the spanning portion). Optionally, the first dielectric layer may be formed in between the first and second longitudinal conductive portions to form the lower surface of the MEMS bridge. It may be that the method comprises forming the first dielectric layer between the first and second longitudinal conductive portions to form the lower surface of the MEMS bridge.

It may be that the first and second longitudinal conductive portions extend along the entirety of the longitudinal edges of the variable capacitor region. It may be that the longitudinal edge of the MEMS bridge is formed entirely of the longitudinal edge of the variable capacitor region. That is, the variable capacitor region may extend from a first anchor to a second anchor.

Optionally, it may be that the MEMS bridge comprises one or more extended sections between each anchor and an edge of the variable capacitor region. Optionally, it may be that the longitudinal edge of the MEMS bridge is formed by the longitudinal edge of the variable capacitor region and the longitudinal edge of the one or more extended sections. That is, the one or more extended sections may comprise a first arm of the MEMS bridge which is located between the first anchor and the first end of the variable capacitor region and a second arm of the MEMS bridge which is located between the second end of the variable capacitor region and a second anchor. Optionally, in some examples, the MEMS bridge (e.g. extended sections) include one or more actuatable conductors (discussed below), which form part of the longitudinal edge of the MEMS bridge between the ends of the variable capacitor region and the respective anchors. It may be that the first and second longitudinal conductive portions each extend laterally across the MEMS bridge by less than a third of the lateral width of the MEMS bridge.

It may be that the first and second longitudinal conductive portions extend laterally in the direction perpendicular to the longitudinal length of the MEMS bridge.

Advantageously, when the MEMS bridge has more surface area without the first conductive layer than with the first conductive layer, there is more resistance to torque caused by the first conductive layer, because the first dielectric layer has a lower stress parameter than the first conductive layer. That is, the larger the amount of first dielectric layer exposed on a surface compared to the amount of first conductive layer, the greater the resistance to torque caused by the first conductive layer, and the less torque actually exerted on the MEMS bridge.

Typically, the first and second longitudinal conductive portions each comprise an inward longitudinal edge and an outward longitudinal edge. It may be that the inward longitudinal edges of the first and second conductive portions are separated (e.g. in the distance perpendicular to the longitudinal direction) by a distance of 3 microns to 30 microns, for example 5 microns to 25 microns, such as 7 microns to 20 microns, for example 10 microns to 15 microns.

It may be that the electrical length between the first and second conductive portions is, for example less than 25%, such as less than 20%, for example less than 15%, such as less than 20% of the wavelength of the RF signal. It may be that the electrical length between the first and second conductive portions is, for example greater than 25%, such as greater than 33%, for example greater than 50%, of the wavelength of the RF signal. By the RF signal we refer to the RF signal conducted by the signal conductor in use. The RF signal may be a signal for which the RF MEMS switch (e.g. the signal conductor) is configured. The RF signal may be the operating RF signal wavelength.

It may be that the first and second longitudinal conductive portions comprise a longitudinal length greater than 400 microns. It may be that the first and second longitudinal conductive portions comprise a longitudinal length greater than 400 microns, 450 microns or 500 microns.

Typically, the lateral edges of the first and second longitudinal conductive portions are shorter than the longitudinal edges of the first and second longitudinal conductive portions. The first and second longitudinal conductive portions may have an equal or different size.

It may be that the first and second longitudinal conductive portions each extend laterally across the MEMS bridge by less than a third, less than 25%, less than 20%, less than 15% or less than 10% of the lateral width of the MEMS bridge.

Optionally, the lower surface of the MEMS bridge may have a total area comprising more of the first dielectric layer than the first conductive layer. The lower surface of the MEMS bridge may have a total area comprising more of the first conductive layer than the first dielectric layer. The lower surface of the MEMS bridge may have a total area comprising over 25%, over 50%, over 75% of the first dielectric layer. The lower surface of the MEMS bridge may have a total area comprising over 25%, over 50%, over 75% of the first conductive layer. The lower surface may have a total area comprising equal amounts of the first conductive layer and the first dielectric layer.

The MEMS bridge is typically symmetrical about a central longitudinal axis. In this way, there is an equal amount of the first conductive layer and the first dielectric layer on the lower surface on either side of the central longitudinal axis.

It may be that the first and second longitudinal conductive portions are not in conductive connection with one another.

It may be that the MEMS switch comprises a first signal conductor and ground conductors supported on the substrate on either side of the first signal conductor and the first and second longitudinal conductive portions form separate parallel variable capacitive connections between the signal conductor and the ground conductors. It may be that the MEMS switch comprises a first signal conductor and a second signal conductor and wherein the first and second longitudinal conductive portions form separate parallel variable capacitive connections between the first and second signal conductors.

By providing the MEMS bridge with a variable capacitor region with separate longitudinal conductive portions, each longitudinal conductive portion forms a capacitive connection between the signal conductor and the ground conductors (in a shunt configuration) or between the signal conductors (in a series configuration). That is, typically, the first longitudinal conductive portion forms a first parallel variable capacitive connection comprising a plurality of capacitances and the second longitudinal conductive portion forms second parallel variable capacitive connection comprising a plurality of capacitances. Typically, in the shunt configuration, the first parallel variable capacitive connection comprises a first capacitance between the section of the first longitudinal conductive portion provided over the signal conductor. Typically, in the shunt configuration, the first parallel variable capacitive connection comprises second and third capacitances between the sections of the first longitudinal conductive portion provided over the ground conductors. Typically, in the shunt configuration, the second parallel variable capacitive connection comprises a fourth capacitance between the section of the second longitudinal conductive portion provided over the signal conductor. Typically, in the shunt configuration, the second parallel variable capacitive connection comprises fifth and sixth capacitances between the sections of the second longitudinal conductive portion provided over the ground conductors. Typically, in the series configuration, the first parallel variable capacitive connection comprises a first capacitance between the section of the first longitudinal conductive portion provided over the first signal conductor. Typically, in the series configuration, the first parallel variable capacitive connection comprises a second capacitance between the section of the first longitudinal conductive portion provided over the second signal conductor. Typically, in the series configuration, the second parallel variable capacitive connection comprises a third capacitance between the section of the second longitudinal conductive portion provided over the first signal conductor. Typically, in the series configuration, the second parallel variable capacitive connection comprises a fourth capacitance between the section of the second longitudinal conductive portion provided over the second signal conductor.

Typically, the capacitances between the variable capacitor region (e.g. the longitudinal conductive portions) and the signal conductor(s) (and between the variable capacitor region (e.g. the longitudinal conductive portions) and the ground conductors) are greater when the variable capacitor region (and thereby the MEMS bridge) is in the second position than in the first position.

Advantageously, since the first and second longitudinal conductive portions are not in conductive connection with one another and form separate parallel variable capacitive connections between the signal conductor(s) (and the ground conductors), it is possible to achieve a higher capacitive area (and therefore a higher change in capacitance) whilst maintaining a high ratio of capacitances between the up and down states.

Optionally, it may be that the first conductive layer comprises one or more third longitudinal conductive portions extending parallel to and between the first and second longitudinal conductive portions. It may be that the one or more third longitudinal conductive portions each extend laterally across the MEMS bridge by less than 25% of the lateral width of the MEMS bridge. It may be that the extension laterally across the MEMS bridge is in the direction perpendicular to the longitudinal length of the MEMS bridge. It may be that the method of providing the first conductive layer comprises providing one or more third longitudinal conductive portions extending parallel to and between the first and second longitudinal conductive portions.

Advantageously, it is possible to achieve a further higher capacitive area (and therefore a higher change in capacitance) whilst maintaining a high ratio of capacitances between the up and down states using one or more third longitudinal conductive portions.

Typically, the one or more third longitudinal portions are generally the same as the first and second longitudinal conductive portions. The one or more third longitudinal conductive portions are typically separated from one another and the first and second longitudinal conductive portions by the first dielectric layer. It may be that the method comprises forming the lower surface of the MEMS bridge by providing the one or more third longitudinal conductive portions separated from one another and the first and second longitudinal conductive portions by the first dielectric layer. That is, the lower surface of the MEMS bridge may comprise alternating strips of the longitudinal conductive portions of the first conductive layer and strips of the first dielectric layer, which extends downwards (i.e. towards the substrate) between the longitudinal conductive portions.

It may be that the one or more third longitudinal conductive portions each extend laterally across the MEMS bridge by less than 25%, less than 20%, less than 15% or less than 10% of the lateral width of the MEMS bridge.

It may be that the MEMS bridge comprises one or more slots extending longitudinally along the MEMS bridge and the one or more slots extending through both the first dielectric layer and the first conductive layer. It may be that the method comprises providing one or more slots extending longitudinally along the MEMS bridge and extending through both the first dielectric layer and the first conductive layer.

Advantageously, the provision of slots in the MEMS bridge reduces the curvature of the MEMS bridge because the absence of the first dielectric layer means that the first and second conductive portions cannot exert torque on the slots of the MEMS bridge.

Optionally, it may be that the one or more slots form gaps in the upper and lower surfaces of the MEMS bridge. That is, the one or more slots typically extend through the entire thickness of the MEMS bridge. The first and second conductive portions, and the one or more third longitudinal conductive portions if present, may be separated from one another with the one or more slots. It may be that the method comprises forming the lower surface of the MEMS bridge by providing the first and second conductive portions, and the one or more third longitudinal conductive portions if present, separated from one another with the one or more slots. For example, the lower surface of the MEMS bridge may be formed of a repeating alternating pattern of a longitudinal conductive portion and a slot across the entire lower surface of the MEMS bridge. In another example, the lower surface of the MEMS bridge may be formed of a longitudinal conductive portion along each longitudinal edge of the variable capacitor region with an alternating patten of a slot and a strip of the first dielectric layer. Advantageously, this arrangement achieves an even higher ratio of capacitances, thereby resulting in a flatter MEMS bridge in the second position. Advantageously, tuning the change in capacitance to a lower value e.g. to apply a smaller increment of phase shift to signals passing along the signal conductor.

It may be that the one or more slots extend laterally across the MEMS bridge in total by greater than 20% of the lateral width of the MEMS bridge. It may be that the one or more slots extend laterally across the MEMS bridge in the direction perpendicular to the longitudinal length of the MEMS bridge.

Advantageously, when the MEMS bridge has a large surface area formed of slots, there is less material of the MEMS bridge that is subject to torque caused by the first and second conductive portions. That is, the lower the amount of the first dielectric layer exposed on a surface of the MEMS bridge compared to the amount of first conductive layer, the lower the surface of the MEMS bridge which is subject to torque caused by the first conductive layer.

Typically, the one or more slots have a shorter lateral length than the longitudinal conductive portions. However, in some examples, the one or more slots may have an equal or longer lateral length than the longitudinal conductive portions. It may be that the one or more slots extend laterally across the MEMS bridge in total by greater than 20%, greater than 30%, greater than 40% or greater than 50% of the lateral width of the MEMS bridge.

It may be that the one or more slots extend longitudinally further towards a respective end of the MEMS bridge than at least one longitudinal edge of the variable capacitor region. It may be that providing the one or more slots comprises providing the one or more slots extending further towards a respective end of the MEMS bridge than at least one longitudinal edge of the variable capacitor region.

Optionally, it may be that the one or more slots extend longitudinally through, at least a part of, the variable capacitor region and at least a part of, the one or more slots.

It may be that the substrate comprises one or more pull-down substrate conductors and the MEMS bridge comprises one or more actuatable conductors located between the anchors and the variable capacitor region. It may be that the one or more actuatable conductors are provided above the one or more pull-down substrate conductors. It may be that the method comprises providing one or more pull-down substrate conductors and one or more actuatable conductors extending above the one or more pull-down substrate conductors between the anchors and the variable capacitor region. Optionally, it may be that providing the one or more actuatable conductors comprises providing an embedded portion which extends longitudinally along the MEMS bridge and between the first and second longitudinal conductive portions.

The embedded portion where present typically extends between the first and second longitudinal conductive portions without contacting them. Thus the one or more actuatable conductors typically remains insulated from the variable capacitor region.

The one or more pull-down substate conductors and the one or more actuatable conductors may typically cause the MEMS bridge to move from the first position to the second position. Optionally, the MEMS bridge may comprise a first actuatable conductor provided over a first pull-down substrate conductor on the substrate and a second actuatable conductor provided over the second pull-down substrate conductor on the substrate. Typically, by applying a potential difference between at least one conductor on the substrate (e.g. the one or more ground conductors, or a signal conductor, or a pull down conductor (a conductor configured to selectively pull down the bridge)) and at least one conductor on the MEMS bridge (e.g. the variable capacitor region or an actuatable conductor of the MEMS bridge) to thereby cause the MEMS bridge to move from the first position (up state) to the second position (down state), (typically wherein variable capacitor region is closer to the substrate in the second position than in the first position), by electrostatic actuation (generating an attractive electrostatic force between the conductors on the substrate and the MEMS bridge and thereby pulling the MEMS bridge down). The potential difference (or biasing potential) may be DC. For example, a method of operating the RF MEMS switch may comprise applying a step change in a DC potential difference. However, the potential difference may be AC, typically with a frequency of less than 10 kHz (or less than 5 kHz). The potential of the actuatable conductor of the MEMS bridge may be changed to cause electrostatic actuation (whether a DC potential or an alternating potential). The potential of a pull-down conductor supported on the substrate may be changed to cause electrostatic actuation (whether a DC potential or an alternating potential). A DC potential offset may be applied to a conductor carrying an RF signal (e.g. the signal conductor). A biasing signal (e.g. a DC signal, or an AC signal, typically with a frequency of less than 10 kHz (or less than 5 kHz)) may be applied to a conductor carrying an RF signal (e.g. the signal conductor).

It may be that at least one of the one or more actuatable conductors comprises an embedded portion which extends longitudinally along the MEMS bridge and between the first and second longitudinal conductive portions. It may be that the embedded portion is provided over at least one of the ground conductors.

Advantageously, provision of an embedded portion in the one or more actuatable conductors further reduces curvature of the bridge in the down state by extending the longitudinal extent of the actuatable conductors and increasing the longitudinal extent of the bridge which is directly held by electromagnetic attraction between conductors.

Optionally, the embedded portion typically corresponds to a portion of the actuatable conductor which is provided on the MEMS bridge between the first and second conductive portion for at least part of the longitudinal length of the first and second conductive portion. It may be that, when the MEMS bridge is in the second position, the embedded portions contact (optionally via an intervening layer) the respective ground conductors above which they are provided.

It may be that the embedded portion is provided at least partially over the ground conductors. In this way, at least part of the embedded portion is provided vertically above the ground conductors.

It may be that at least one of the one or more actuatable conductors comprises one or more slots extending longitudinally along a portion of the MEMS bridge. It may be that the method comprises providing one or more slots in at least one of the one or more actuatable conductors.

Typically, each actuatable conductor may comprise one or more slots. The one or more slots of the at least one actuatable conductor are typically through the entire thickness of the actuatable conductor. That is, the one or more slots may form gaps in the actuatable conductor. The one or more slots may extend through the embedded portion of the actuatable conductor. It may be that the one or more slots have a total lateral length greater than 20%, greater than 30%, greater than 40% or greater than 50% of the longest lateral length of the actuatable conductor. It may be that at least one of the one more slots have a width of less than 5 microns, less than 3 microns, less than 2 microns, less than 1 micron or less than 0.5 microns.

Advantageously, the provision of the one or more slots lowers the voltage at which the transverse (secondary) collapse occurs, allowing the bridge to be pulled flat towards the substrate (e.g. in the on state) at a lower voltage.

It may be that the RF MEMS switch comprises one or more dimples between one or more actuatable conductors and the one or more pull-down substrate conductors. It may be that the method comprises providing one or more dimples between one or more actuatable conductors and the one or more pull-down substrate conductors.

Optionally, the one or more dimples may be provided on the surface of the one or more actuatable conductors facing the substrate. Optionally, the one or more dimples may be provided on the surface of the pull-down substrate conductors facing the MEMS bridge. The one or more dimples may typically be formed of an insulating material. It may be that the one or more dimples are discrete regions of insulating material, that are optionally formed in a pattern on the pull-down substrate conductors or the actuatable conductors.

Advantageously, the one or more dimples prevent the pull-down substrate conductor from contacting the one or more actuatable conductors when the MEMS bridge (and variable capacitor region) is in the second position by acting as mechanical stand-offs to prevent a DC short to ground. In addition, the size and spacing of the one or more dimples can be selected to reduce or prevent stiction.

It may be that the MEMS bridge comprises a second dielectric layer provided between the first conductive layer and the at least one signal conductor. It may be that the second dielectric layer is provided on at least one of: the signal conductor and the first conductive layer. It may be that the MEMS bridge comprises a second dielectric layer provided between the first conductive layer and the signal conductor and the ground conductors. It may be that the second dielectric layer is provided on at least one of: the signal conductor, the ground conductors and the first conductive layer.

Typically, the second dielectric layer is a solid electrically insulating layer. The second dielectric layer is provided between the variable capacitor region (i.e. the longitudinal conductive portions) and the signal conductor (so as to prevent a short circuit between them when the variable capacitor region/MEMS bridge is in the second position). Typically, a second dielectric layer is provided between the variable capacitor region (i.e. the longitudinal conductive portions) and the (respective) ground conductor(s). Optionally, the second dielectric layer may be provided on the surface of the longitudinal conductive portions facing the substrate or the surface of the signal and/or ground conductors facing the MEMS bridge.

It may be that the second dielectric layer comprises one or more pads on at least one of: the signal conductor and the ground conductors. It may be that the change in capacitances between the first position and the second position is dependent on dimensions of the one or more pads. It may be that an electrical permittivity of the one or more pads is greater than a relative permittivity, normalised to air, of 1.

This in itself is believed to be novel, therefore according to a third aspect of the present invention, there is provided a circuit comprising a plurality of radio frequency, RF, microelectromechanical systems, MEMS, switches comprising: a substrate; a signal conductor supported on the substrate; ground conductors supported on the substrate on either side of the signal conductor; and a MEMS bridge at least one end of which is mechanically connected to the substrate by way of at least one anchor. The MEMS bridge comprises a MEMS bridge comprising a variable capacitor region provided over the signal conductor and the ground conductors. The MEMS bridge is deformable from a first position in which the variable capacitor portion is spaced from the respective signal and ground conductor(s) to a second position in which the variable capacitor region is closer to the respective signal and ground conductor(s) than in the first position by way of an electrostatic actuation force. It may be that the capacitances between the variable capacitance region and the signal conductor and the ground conductors are greater when the MEMS bridge is in the second position than when the MEMS bridge is in the first position. The variable capacitor region comprises a first dielectric layer and a first conductive layer. The first conductive layer is positioned on a surface of the first dielectric layer facing the substrate. The variable capacitor region further comprises a second dielectric layer provided between the first conductive layer and the signal conductor and the ground conductors. The second dielectric layer comprises one or more pads on the signal conductor and the ground conductor. The change in capacitance between the first position and the second position is dependent on dimensions of the one or more pads. The circuit comprises RF MEMS switches comprising different dimensioned one or more pads so the change in capacitance between the first position and the second position of the RF MEMS switches is different.

According to a fourth aspect of the invention, there is provided a method of manufacturing a circuit according to the third aspect of the present invention. The method comprises: providing a substrate; providing a signal conductor and ground conductors on either side of the signal conductor supported by the substrate; and providing a MEMS bridge comprising a variable capacitor region over the signal conductor and the ground conductors by providing a first dielectric layer, a first conductive layer and a second dielectric layer. The first conductive layer is provided on the surface of the first dielectric layer facing the substrate and the second dielectric layer is provided between the first conductive layer and the signal conductor and the ground conductors. The method of providing the second dielectric layer comprises providing one or more pads on the signal conductor and the ground conductor and providing the one or pads comprises selecting a change in capacitance between the first position and the second position and selecting dimensions of the one or more pads in dependence on the selected change in capacitance.

Advantageously, the larger the surface area of the contact area between the one or more pads and the respective conductor, the greater the change in capacitance between the up and down states of the MEMS bridge. The one or more pads affect the change in capacitance achieved when the MEMS bridge moves from the up to the down state because the one or more pads are typically formed of a material with an electrical permittivity substantially higher than that of air, e.g. a dielectric material. Therefore, when the MEMS bridge is in the down state, the one or more pads form the bulk of the capacitive gap, so the capacitance is substantially increased relative to a capacitor of the same dimensions and spacing in which the capacitive gap is filled with air.

It may be that an electrical permittivity of the one or more pads is greater than a relative permittivity, normalised to air, of 1.25. It may be that an electrical permittivity of the one or more pads is greater than a relative permittivity, normalised to air, of 5. It may be that an electrical permittivity of the one or more pads is greater than a relative permittivity, normalised to air, of 2.

Advantageously, the dimensions of the one or more pads vary the capacitance of the MEMS switch between the first and second position because the electrical permittivity of the one or more pads is higher than that of air. As a result, the dimensions of the one or more pads determine the change in capacitance. In comparison, if the electrical permittivity of the one or more pads is the same as air, the one or more pads would function primarily as spacers. The actuation of the MEMS switch will also cause capacitance that is air bridged, however this is capacitance will be lower than that of the capacitance of the one or more pads.

It may be that the one or more pads typically have three dimensions. It may be that the one or more pads comprise a surface area (e.g. in a plane extending perpendicular to the direction of movement of the MEMS bridge between the first position and the second position). It may be that the one or more pads comprise a thickness (e.g. in a direction extending parallel to the direction of movement of the MEMS bridge between the first position and the second position).

It may be that the selected change in capacitance is provided by changing the dimensions of the pads. It may be the one or more pads have a different cross-sectional area (e.g. in a plane extending perpendicular to the direction of movement of the MEMS bridge between the first position and the second position) and a constant thickness. That is, it may be that providing the selected change in capacitance between the first position and the second position comprises changing the cross-sectional area of the one or more pads.

It may be the one or more pads have a constant cross-sectional area (e.g. in a plane extending perpendicular to the direction of movement of the MEMS bridge between the first position and the second position) and a different thickness. That is, it may be that providing the selected change in capacitance between the first position and the second position comprises changing the thickness of the one or more pads.

It may be that the change in capacitance between the first position and the second position is dependent on the surface area of the one or more pads. It may be that the greater the surface area of the one or more pads, the greater the change in capacitance between the first position and the second position of the MEMS bridge.

It may be that the change in capacitance between the first position and the second position is dependent on the thickness of the one or more pads. It may be that the greater the thickness of the one or more pads, the greater the change in capacitance between the first position and the second position of the MEMS bridge.

It may be that the dimensions of the one or more pads providing a lower change in capacitance comprise a length of at least 50 microns and a width of at most 4 microns. It may be that the dimensions of the one or more pads providing a greater change in capacitance comprise a length of at least 50 microns and a width of at least 50 microns. It may be that the dimensions of the one or more pads providing a lower change in capacitance comprise a surface area of at most 10% of the area where the variable capacitor overlaps the co-planar waveguide conductors. It may be that the dimensions of the one or more pads providing a greater change in capacitance comprise a surface area of at least 95% of the area where the variable capacitor overlaps the co-planar waveguide conductors.

Optionally, the RF MEMS switch comprises one or more pads on both the signal conductor and the ground conductor(s). Typically, to maximise the change in capacitance for a given signal, the total area of the one or more pads on the ground conductor below the variable capacitor region must equal the total area of the one or more pads on the signal conductor below the variable capacitor region. In this way, the dimensions of the one or more pads may be used to tune the change in capacitance for identical bridge designs, because reducing the total area of the one or more pads below the variable capacitor region will reduce the change in capacitance from when the bridge is in the up state compared to the down state. This technique can be used to create RF MEMS switches to implement smaller increments of phase shift without altering the design of the MEMS bridge.

It may be that the one or more pads with the variable capacitor region are stand-offs or dielectric landing pads (DLPs). Typically, the one or more pads with a large area relative to the surface of the respective signal and ground conductor(s) upon which the one or more pads are placed cause a greater change in capacitance between the MEMS bridge in the first position and the MEMS bridge in the second position.

It will be understood that any features described above in relation to the RF MEMS switches may also be optional features of the other aspects of the invention, for example a method of the invention or a circuit of the invention. Steps in the method may be carried out in the order described herein, or in some cases in another order. In some cases, one or more steps in the method may be carried out simultaneously.

### DESCRIPTION OF THE DRAWINGS

An example embodiment of the present invention will now be illustrated with reference to the following Figures in which:

FIGS. 1 to 21 illustrate an RF MEMS switch according to the present invention;

FIG. 22 illustrates a simplified circuit diagram of the key capacitances in the MEMS bridge;

FIGS. 23 and 24 illustrate an RF MEMS switch according to an example of the prior art;

FIGS. 25 and 26 illustrate an RF MEMS switch according to the present invention;

FIGS. 27 and 28 illustrate a flowchart of a method according to the present invention; and

FIGS. 29 to 30 illustrate an RF MEMS switch according to the present invention.

### DETAILED DESCRIPTION OF AN EXAMPLE EMBODIMENT

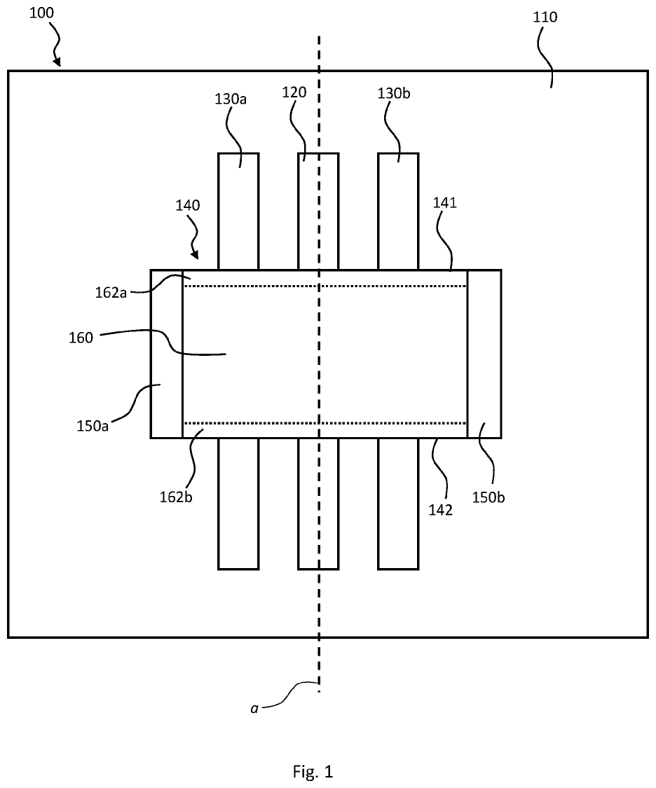

FIG. 1 illustrates a radio frequency, RF, microelectromechanical MEMS, switch 100 according to the present invention from a plan view. The RF MEMS switch 100 comprises a substrate 110 which functions as the base of the RF MEMS switch 100. The RF MEMS switch 100 comprises a signal conductor 120 with ground conductors 130a, 130b arranged on either side. The MEMS bridge is indicated generally by reference numeral 140 and comprises a variable capacitor region 160. The variable capacitor region 160 has a first longitudinal edge 141 and a second longitudinal edge 142. The MEMS bridge 140 is connected to the substrate 110 by an anchors 150a, 150b. The variable capacitor region 160 extends over the signal conductor 120 and the ground conductors 130a, 130b. The longitudinal direction extends from left to right of the drawing and the lateral direction extends from bottom to top of the drawing. The MEMS bridge has a thickness which would extend into the drawing.

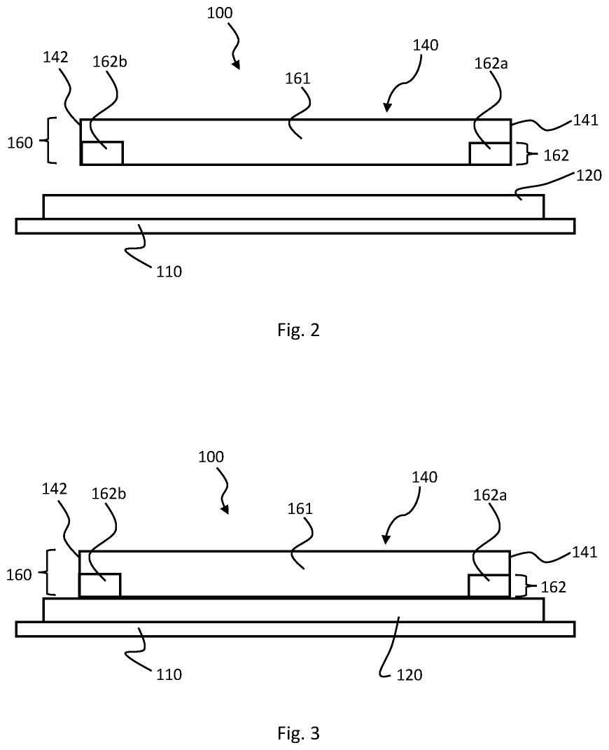

FIGS. 2 and 3 illustrate the RF MEMS switch 100 according to the present invention from a side view along plane a shown in FIG. 1. The variable capacitor region 160 comprises the first dielectric layer 161 and the first conductive layer 162. The first conductive layer 162 comprises a first conductive longitudinal portion 162a and a second longitudinal conductive portion 162b which are separated laterally across the variable capacitor region 160. The first dielectric layer 161 extends towards the substrate 110 between the first and second longitudinal conductive portions 162a, 162b. The first longitudinal conductive portion 162a extends along the first longitudinal edge 141. The second longitudinal conductive portion 162b extends along the second longitudinal edge 142. The first and second longitudinal conductive portions 162a, 162b extend along the entirety of the longitudinal edges of the variable capacitor region 160. Since the first dielectric layer 161 is insulating, there is no conductive connection between the first and second longitudinal conductive portions 162a, 162b.

The first and second longitudinal conductive portions 162a, 162b are shown in the plan view of FIG. 1 using a dotted line because they would not typically be visible from the plan view but have been included for illustrative purposes to aid understanding.

FIG. 2 shows the MEMS bridge 140 in a first position in which the MEMS bridge 140 is not in contact with the signal conductor 120 or the ground conductors 130a, 130b. FIG. 3 shows the MEMS bridge 140 in a second position in which the MEMS bridge 140 is in contact with the signal conductor 120 and the ground conductors 130a, 130b. The variable capacitor region 160 is closer to the signal conductor 120 and the ground conductors 130a, 130b in FIG. 3 than in FIG. 2. The MEMS bridge 140 moves between the first position and the second position due to an electrostatic actuation force.

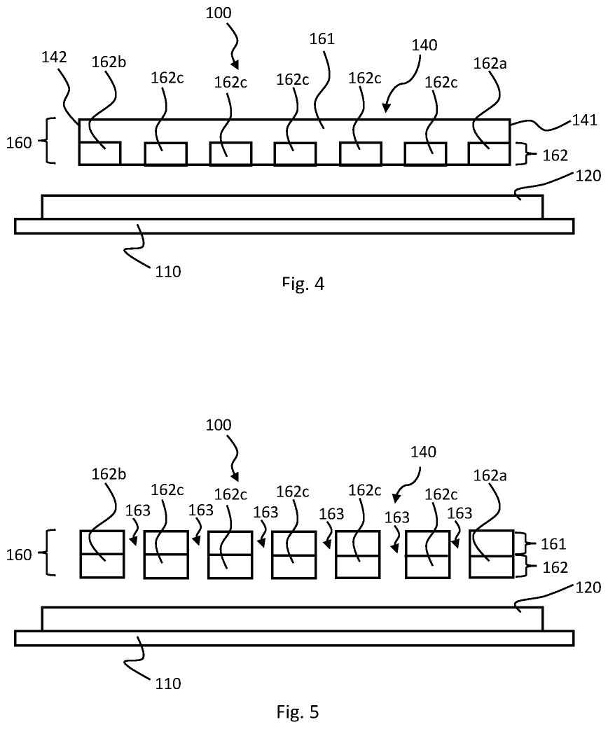

FIG. 4 shows the MEMS bridge 140 with a first conductive layer 162 comprising five third longitudinal conductive portions 162c which are parallel to the first longitudinal conductive portion 162a and the second longitudinal conductive portion 162b.

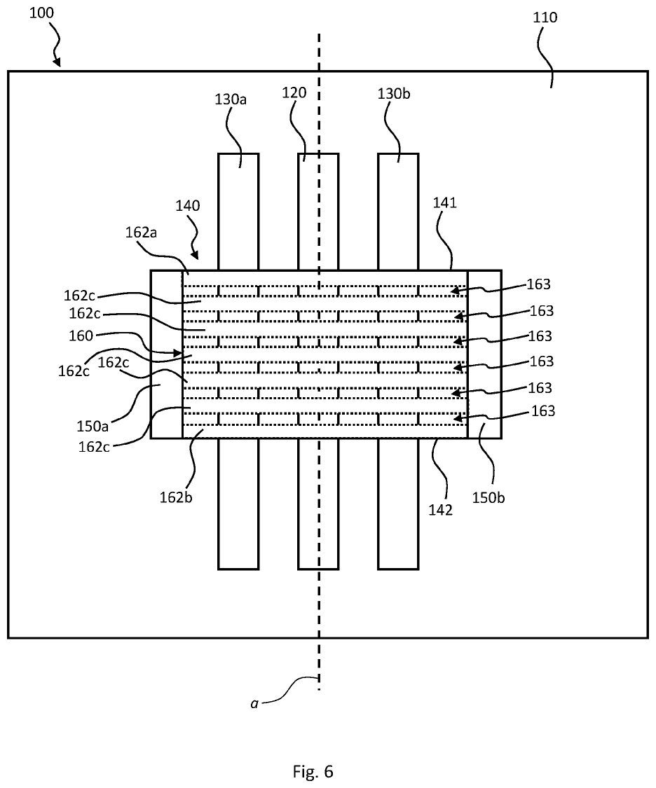

FIG. 5 shows the MEMS bridge 140 of FIG. 4 with the addition of six slots 163 extending longitudinally along the MEMS bridge 140 in the same direction as the longitudinal conductive portions, 162a, 162b, 162c. The slots 163 form gaps in the MEMS bridge 140 because the slot is through the first dielectric layer 161 and the first conductive layer 162. FIG. 6 illustrates the MEMS bridge of FIG. 5 from a plan view. As shown in FIG. 6, the slots 163 form gaps in the MEMS bridge 160. Although not typically visible from the plan view, the MEMS bridge 140 of FIG. 6 also includes a first longitudinal conductive portion 162a along the first longitudinal edge 141, a second longitudinal conductive portion 162b along the second longitudinal edge 142 and the third longitudinal conductive portions 163c between the first and second longitudinal conductive portions 162a, 162b.

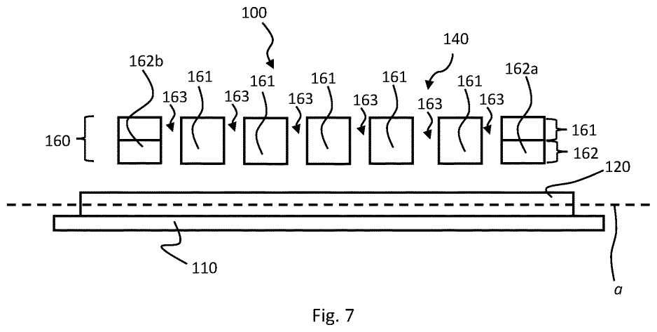

FIG. 7 shows the MEMS bridge 140 of FIGS. 2 and 3 with only the first and second conductive portions 162a, 162b and the addition of six slots 163. It will be appreciated that the edge of the variable capacitor region 160 or the anchors 150a, 150b would be visible in the cross section where the slots 163 are located. However, for clarity and illustrative purposes, these features are not illustrated.

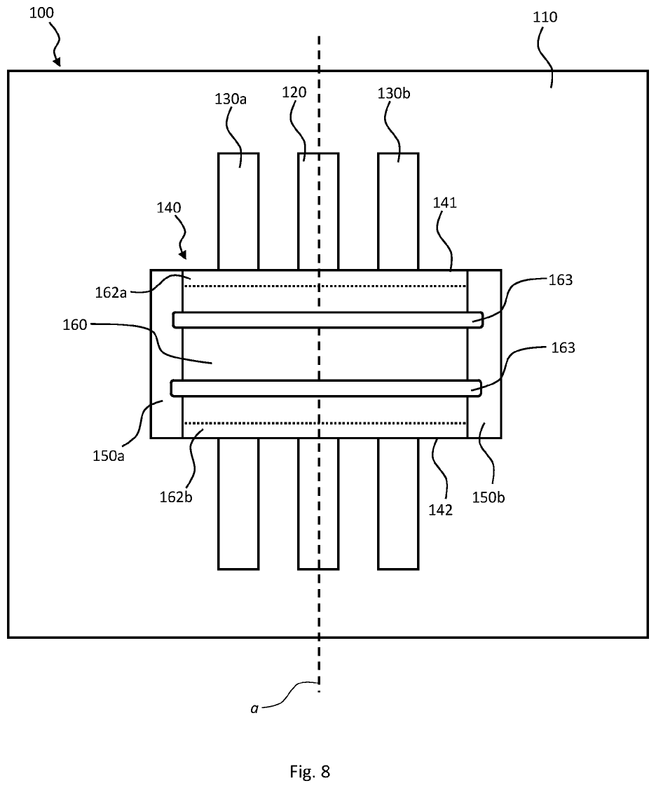

FIG. 8 shows a MEMS bridge 140 with two slots 163 from a plan view. Although not typically visible from the plan view, the MEMS bridge 140 of FIG. 8 also includes a first longitudinal conductive portion 162a along the first longitudinal edge 141 and a second longitudinal conductive portion 162b along the second longitudinal edge 142. The slots extend further longitudinally than the first and second longitudinal edges 141, 142 of the variable capacitor region 160.

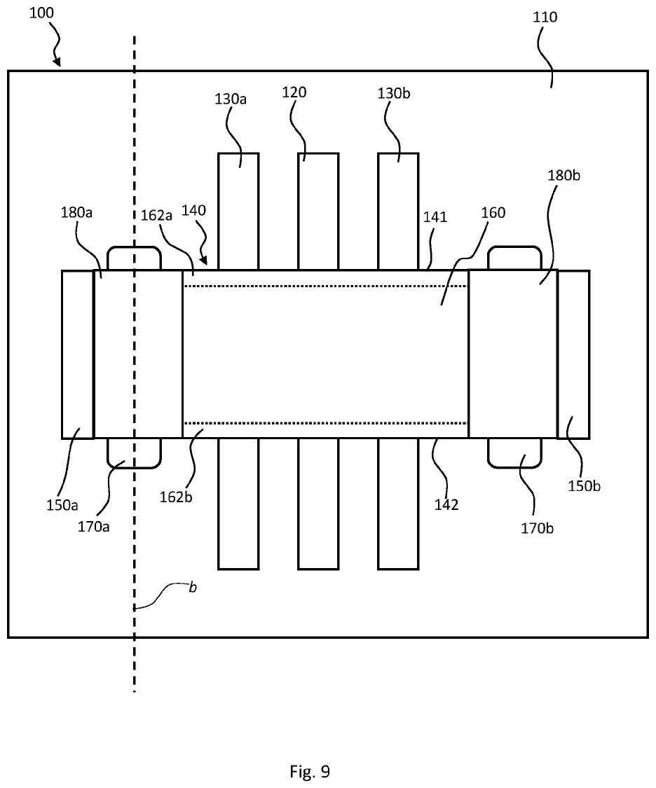

FIG. 9 shows the MEMS bridge 140 of FIG. 1 in which the substrate 110 comprises two pull-down substrate conductors 170a, 170b. The substrate 110 comprises a pull-down substrate conductor 170a between the first anchor 150a and the first ground conductor 130a and also a pull-down substrate conductor 170b between the second ground conductor 130b and the second anchor 150b. The MEMS bridge 140 comprises two actuatable conductors 180a, 180b. The MEMS bridge 140 comprises an actuatable conductor 180a between the first anchor 150a and the variable capacitor region 160. The MEMS bridge 140 comprises an actuatable conductor 180b between the variable capacitor region 160 and the second anchor 150b. Each actuatable conductor 180a, 180b is positioned above a respective pull-down substrate conductor 170a, 170b.

The electrostatic attraction which causes the MEMS bridge 140 to move between the first position and the second position is provided by applying a bias to the actuatable conductors 180a, 180b. The actuatable conductors 180a, 180b are selectively electrostatically attracted to the pull-down substrate conductors 170a, 170b.

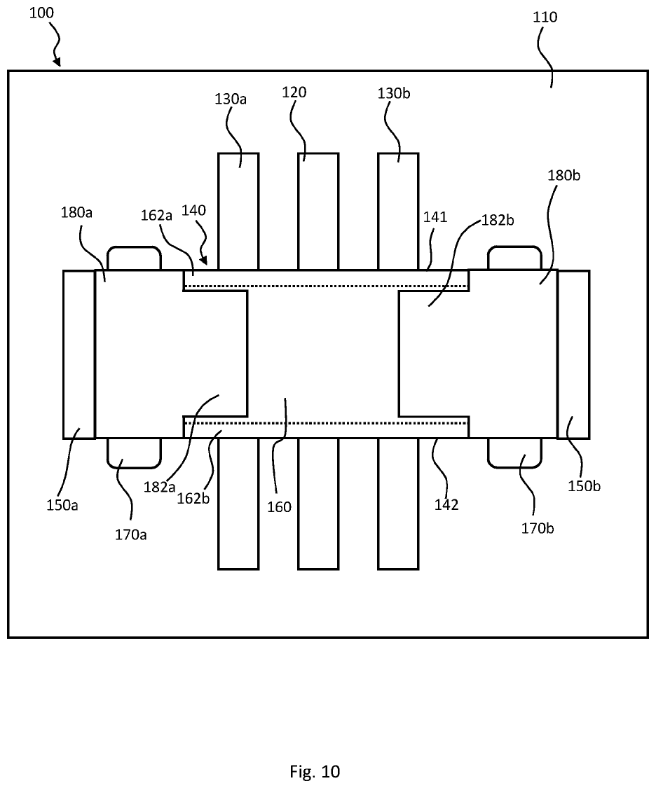

FIG. 10 shows the MEMS bridge 140 of FIG. 9 in which the actuatable conductors 180a, 180b each comprise an embedded portion 182a, 182b. Each embedded portion 182a, 182b extends into the variable capacitor region 160 between the first and second longitudinal conductive portions 162a, 162b. The embedded portions 182a, 182b are formed partially over the ground conductors 130a, 130b respectively.

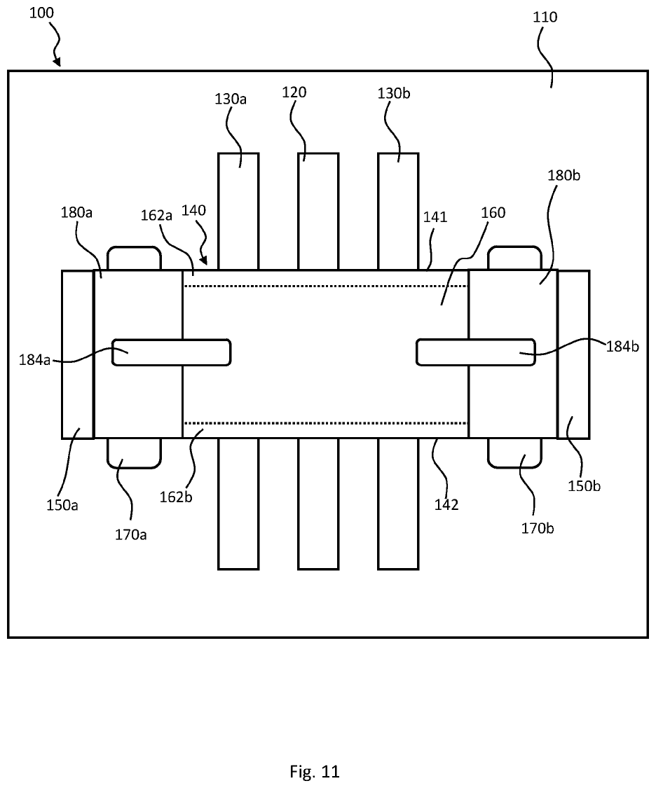

FIG. 11 shows the MEMS bridge 140 of FIG. 9 with a slot 184 extending longitudinally through each actuatable conductor 180a, 180b. The slots 184 also extend partially into the variable capacitor region 160.

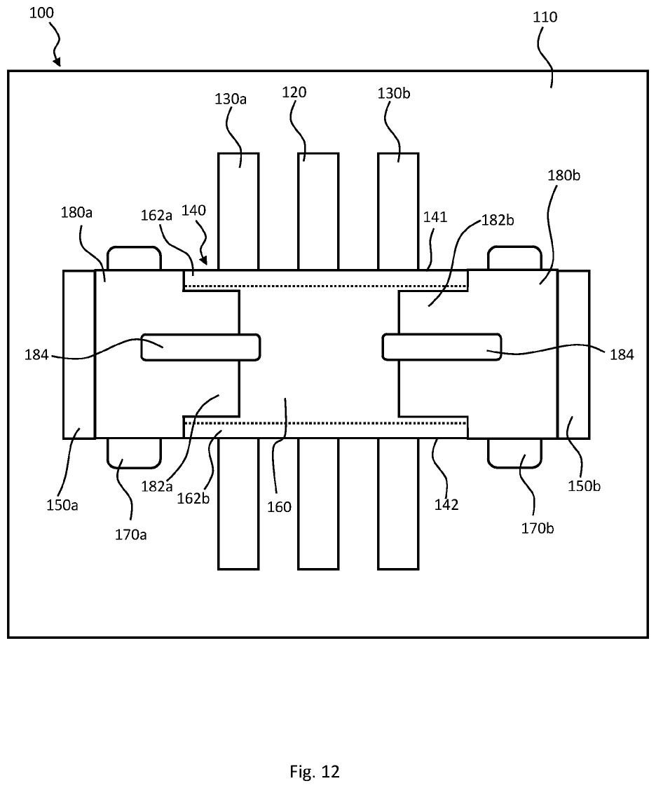

FIG. 12 shows the MEMS bridge 140 of FIG. 10 with a slot 184 extending longitudinally through each embedded portion 182a, 182b of the actuatable conductor 180a, 180b.

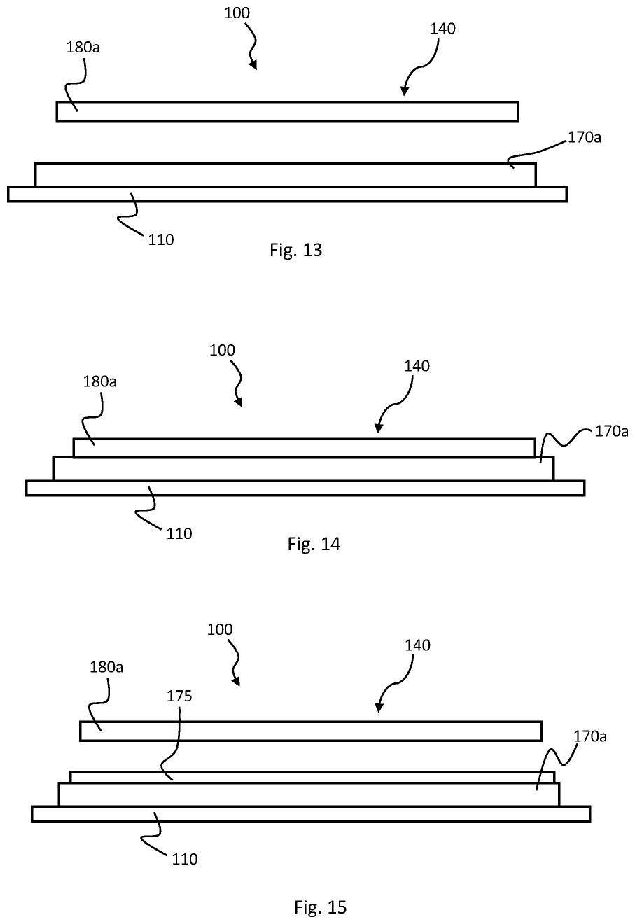

FIG. 13 shows the cross section of the MEMS bridge 140 of FIG. 9 along plane b in a first position in which there is no electrostatic attraction between the pull-down substrate conductor 170a and the actuatable conductor 180a. FIG. 14 shows the cross section of FIG. 13 in which the MEMS bridge 140 is in a second position in which there is an electrostatic attraction between the pull-down substrate conductor 170a and the actuatable conductor 180a so the actuatable conductor 180a is pulled down towards the pull-down substrate conductor 170a.

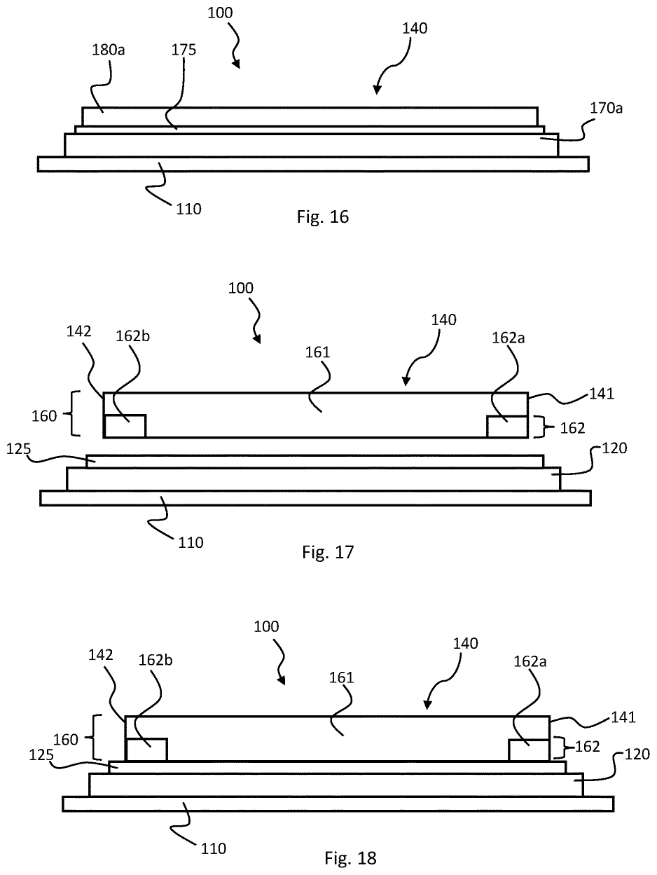

FIG. 15 shows the cross section of the MEMS bridge 140 of FIG. 9 along plane b in which the pull-down substrate conductor 170a has a dimple 175 on the top surface of the pull-down substrate conductor 170. The MEMS bridge 140 is shown in a first position in which there is no electrostatic attraction between the pull-down substrate conductor 170a and the actuatable conductor 180a. FIG. 16 shows the cross section of FIG. 15 in which the MEMS bridge 140 is shown in a second position in which there is an electrostatic attraction between the pull-down substrate conductor 170a and the actuatable conductor 180a. The top surface of pull-down substrate conductor 170a is not in contact with the actuatable conductor 180a when the MEMS bridge 140 is in the second position because the actuatable conductor 180a is in contact with the dimple 175 because the dimple 175 is on top of the pull-down substrate conductor 170a.

FIG. 17 shows the cross section of the RF MEMS switch shown in FIG. 1 along plane a in which the signal conductor 120 has a second dielectric layer 125. The second dielectric layer 125 is formed of one pad. The MEMS bridge 140 is shown in a first position in which there is no electrostatic attraction between the MEMS bridge 140 and the substrate 110. FIG. 18 shows the cross section of FIG. 17 in which the MEMS bridge 140 is shown in a second position in which there is an electrostatic attraction between the MEMS bridge 140 and the substrate 110. The top surface of signal conductor 120 is not in contact with the variable capacitor region 160 because the variable capacitor region is in contact with the pad 125 because the pad 125 is on top of the signal conductor 120.

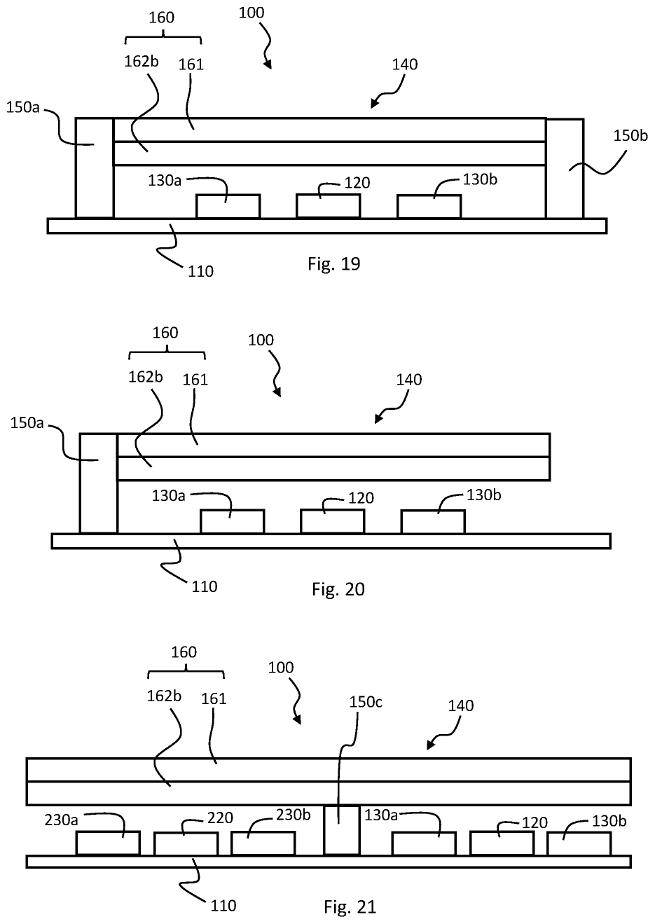

FIG. 19 shows a cross section of a MEMS bridge 140 taken along the second longitudinal edge 142. In FIG. 19, the MEMS bridge 140 has opposing first and second lateral edges which form the ends of the second longitudinal edge 142 and are each connected to the substrate 110 by two anchors 150a, 150b, respectively. FIG. 20 shows a cross section of a MEMS bridge 140 taken along the second longitudinal edge 142. In FIG. 20, the MEMS bridge 140 has opposing first and second lateral edges which form the ends of the second longitudinal edge 142. Only the first end is mechanically connected to the substrate 110 by way of one anchor 150a. Therefore, the MEMS bridge 140 in FIG. 20 is cantilevered. FIG. 21 shows a cross section of a MEMS bridge 140 taken along the second longitudinal edge 142. In FIG. 21, the MEMS bridge 140 has opposing first and second lateral edges which form the ends of the second longitudinal edge 142. Neither the first nor the second end are connected to an anchor. Instead, a centre part of the MEMS bridge 140 is connected to a central anchor 150c. The substrate 110 in FIG. 21 also includes a second set of ground conductors 230a, 230b and a second signal conductor 220. The MEMS bridge 140 is attracted to either the first set of conductors (120, 130a, 130b) or the second set of conductors (220, 230a, 230b). The central anchor 150c functions as a pivot and the RF MEMS switch 100 is a teeter-totter switch.

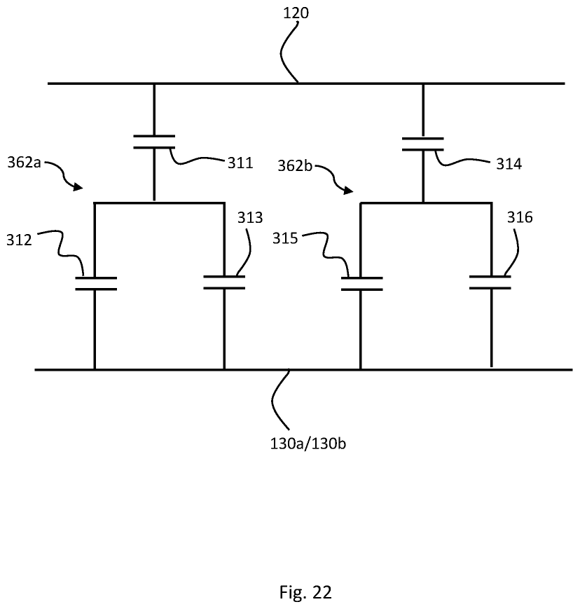

FIG. 22 shows a simplified circuit diagram of the key capacitances in the MEMS bridge 140 from FIG. 1. The simplified circuit diagram includes two separate parallel variable capacitive connections between the signal conductor and the ground conductors. The first longitudinal conductive portion 162a forms first parallel variable capacitive connection 362a and the second longitudinal conductive portion 162b forms second parallel variable capacitive connection 362b. The top line represents the signal conductor 120. The bottom line represents the ground conductors 130a, 130b. Taking the first parallel variable capacitive connection 362a, capacitance 311 is the capacitance between the middle of the first longitudinal conductive portion 162a and the signal conductor 120. This capacitance is low when the MEMS bridge 140 (and therefore the variable capacitor region 160) is in the first position but is much higher when the MEMS bridge 140 is in the second position. Capacitances 312, 313 are the capacitances between the edges of the first longitudinal conductive portion 162a and the ground conductors 130a, 130b. Again, when the bridge is in the second position, these capacitances are much increased. The capacitances 312 and 313 are in parallel and their combined capacitance is in series with capacitance 311.

Taking the second parallel variable capacitive connection 362b, capacitance 314 is the capacitance between the middle of the second longitudinal conductive portion 162b and the signal conductor 120. This capacitance is low when the MEMS bridge 140 (and therefore the variable capacitor region 160) is in the first position but is much higher when the MEMS bridge 140 is in the second position. Capacitances 315, 316 are the capacitances between the edges of the longitudinal conductive portion 162b and the ground conductors 130a, 130b. Again, when the bridge is in the second position, these capacitances are much increased. The capacitances 315 and 316 are in parallel and their combined capacitance is in series with capacitance 314.

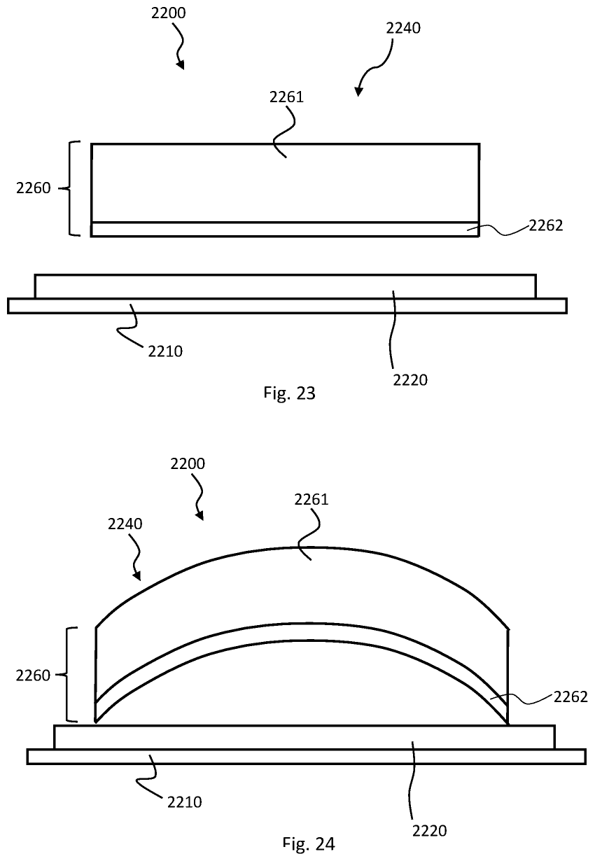

FIGS. 23 and 24 illustrate a cross section of an RF switch according to an example of the prior art. The RF MEMS switch 2200 differs from the RF MEMS switch 100 of the present invention in that the MEMS bridge 2240 has a variable capacitor region 2260 which includes a continuous first conductive layer 2262 underneath the first dielectric layer 2261. The continuous first conductive layer 2262 covers the entirety of the first dielectric layer 2261. The MEMS bridge 2240 is provided over a signal conductor 2220 supported on a substrate 2210. FIG. 23 shows the MEMS bridge 2240 in a first position. FIG. 24 shows the MEMS bridge 2240 in a second position. Due to the high stress differential between the first dielectric layer 2261 and the first conductive layer 2262, when the MEMS bridge 2240 is actuated from the first position to the second position, the MEMS bridge 2240 experiences transverse warping due to torque in each of the two layers 2261, 2262. The transverse warp causes the ratio of capacitance between up state and the down state of the MEMS bridge 2240 and the substrate 2210 to be less than it would be if the MEMS bridge 2240 was flat in the second position.

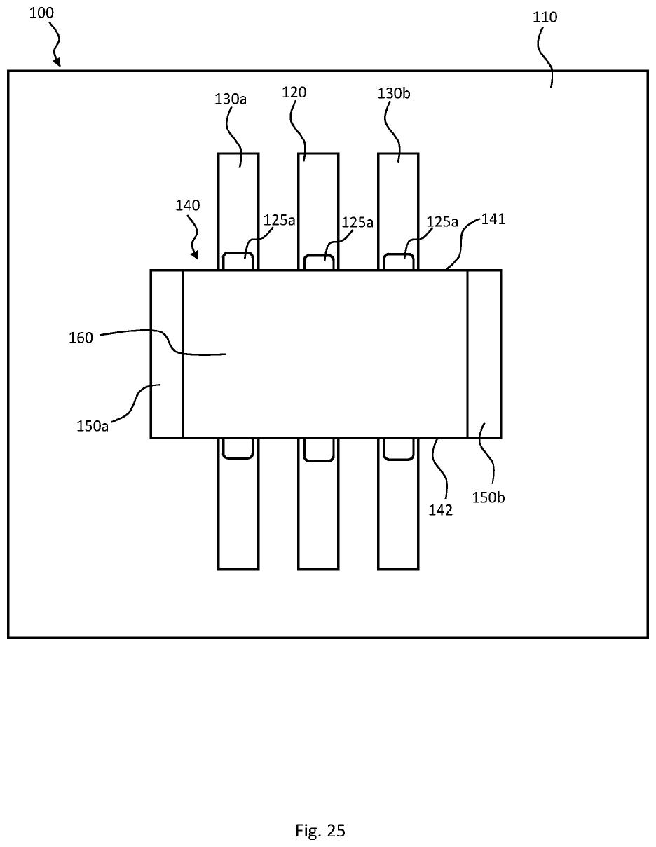

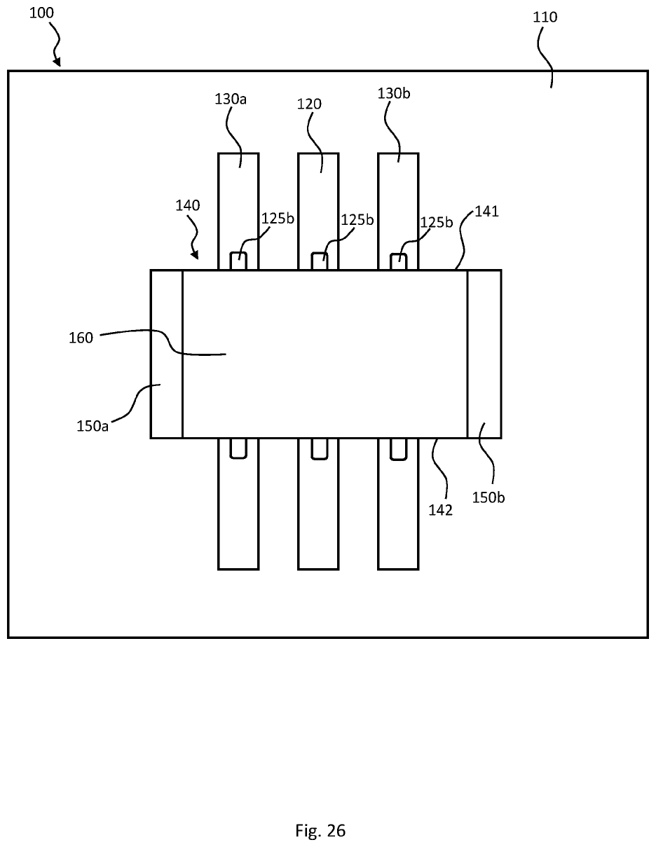

FIG. 25 shows a MEMS bridge 140 with a pad 125a on each of the ground conductors 130a, 130b and the signal conductor 120. FIG. 26 shows the MEMS bridge 140 of FIG. 25 with a different sized pad 125b on each of the ground conductors 130a, 130b and the signal conductor 120. The MEMS bridges shown in FIGS. 25 and 26 are identical except for the size of the pads 125a, 125b. As shown, the pads 125a are wider than the pads 125b. The pads 125a cause a greater change in capacitance between the up and down states of the MEMS bridge than the pads 125b. Since the total area underneath the pads 125a is greater than the total area underneath the pads 125b, the change in capacitance between the first and second positions of the MEMS bridge 140 in FIG. 25 is greater for the change in capacitance between the first and second positions of the MEMS bridge 140 in FIG. 26. In some examples, the MEMS bridge shown in FIGS. 25 and 26 are part of a circuit.

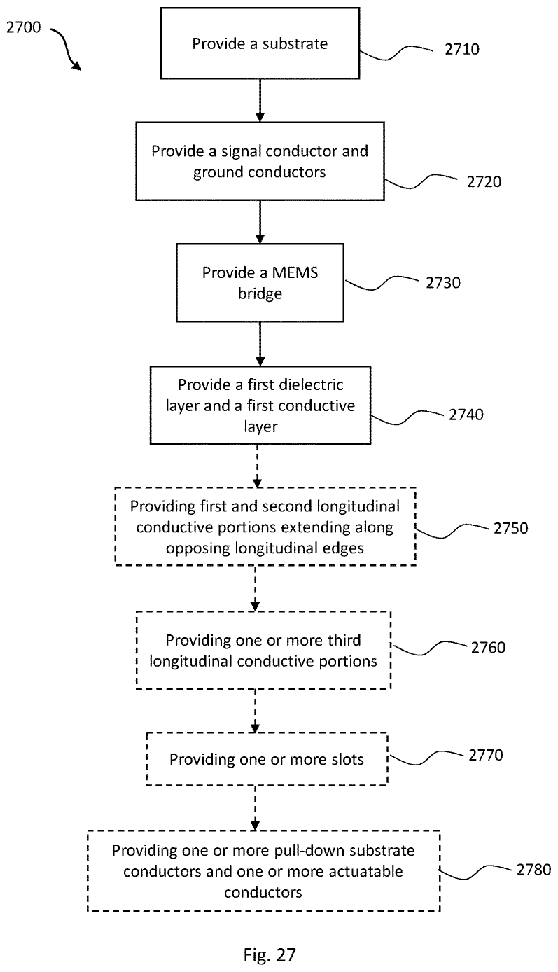

FIG. 27 illustrates a method 2600 according to the present invention. In particular, the method 2700 is a method of manufacturing an RF MEMS switch as described above. As part of the manufacturing process, a substrate is provided 2710 and a signal conductor and a ground conductor on either side of the substrate are provided 2720 on the surface of the substrate. A MEMS bridge, which includes a variable capacitor region, is then provided 2730 on the substrate over the signal conductor and the ground conductors. The variable capacitor region of the MEMS bridge is formed by providing 2740 a first dielectric layer and a first conductive layer. The first conductive layer is underneath the first dielectric layer and is formed of at least two separate conductive portions. In particular, the first conductive layer is provided by forming at least a first longitudinal conductive portion and a second longitudinal conductive portion which are spaced apart in a direction perpendicular to the longitudinal length of the MEMS bridge. The method 2700 may also include the further method steps shown in dashed lines on

FIG. 27. Method step 2750 describes a method for providing the first conductive layer in which first and second longitudinal conductive portions are provided 2750. The first and second conductive portions are provided to extend along opposing longitudinal edges of the variable capacitor region like the first and second conductive portions 162a, 162b shown in FIG. 1.

Method step 2760 is another method for providing the first conductive layer in which one or more third longitudinal conductive portions are provided 2760. These one or more third longitudinal conductive portions are provided to extend parallel to and between the first and second longitudinal conductive portions like the third conductive portions 162c shown in FIG. 4.

The method 2700 may comprise the method step of providing 2770 one or more slots. The slots are provided to extend longitudinally along the MEMS bridge through both the first dielectric and first conductive layers like the slots 163 shown in FIG. 5.

The method 2700 may comprise providing 2780 one or more pull-down substrate conductors and one or more actuatable conductors. The pull-down substrate conductors are provided on the substrate and the one or more actuatable conductors are provided on the MEMS bridge. The one or more actuatable conductors are provided to extend above the one or more pull-down substrate conductors between the anchors and the variable capacitor region. The method step 2780 of providing the one or more actuatable conductors may, in some examples, comprise providing an embedded portion as shown in FIG. 10.

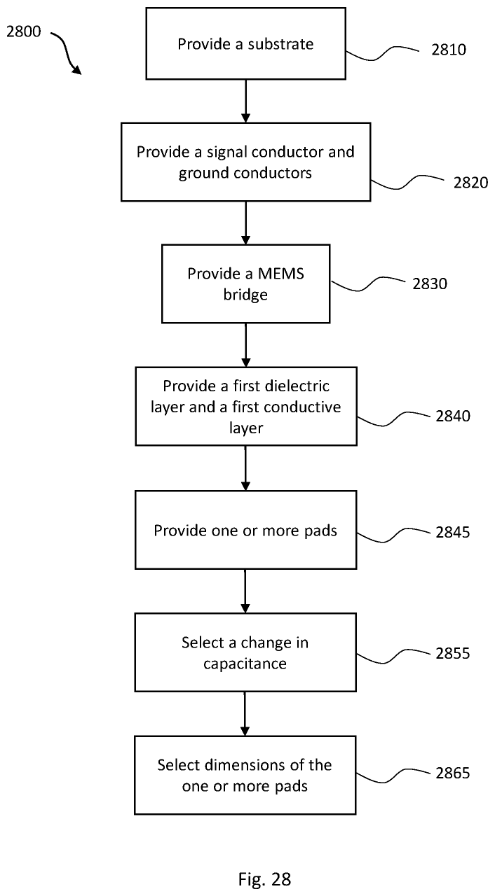

FIG. 28 illustrates a method 2800 according to the present invention. The method 2800 is a method of manufacturing a circuit with a plurality of RF MEMS switches, such as those shown in FIGS. 25 and 26. The method 2800 comprises method steps 2810 to 2840, which are the same as method steps 2710 to 2740 of the method 2700 shown in FIG. 27. Method 2800 comprises method step 2845 which comprises providing the second dielectric layer by providing one or more pads on the signal conductor and the ground conductors, such as the pads 125a, 125b shown in FIGS. 25 and 26.

The dimensions of the pads provided on the signal conductor and the ground conductors are chosen so that they provide a desired change in capacitance when the MEMS bridge moves from the first position to the second position and the second position to the first position. Therefore, the method 2800 comprises selecting 2855 a desired change in capacitance to occur when the MEMS bridge moves from the first position and the second position and the second position to the first position. The method 2800 also comprises selecting 2865 dimensions of the one or more pads in dependence on the desired change in capacitance. The one or more pads are then provided on the signal conductor and the ground conductors with the dimensions that correspond to the desired change in capacitance.

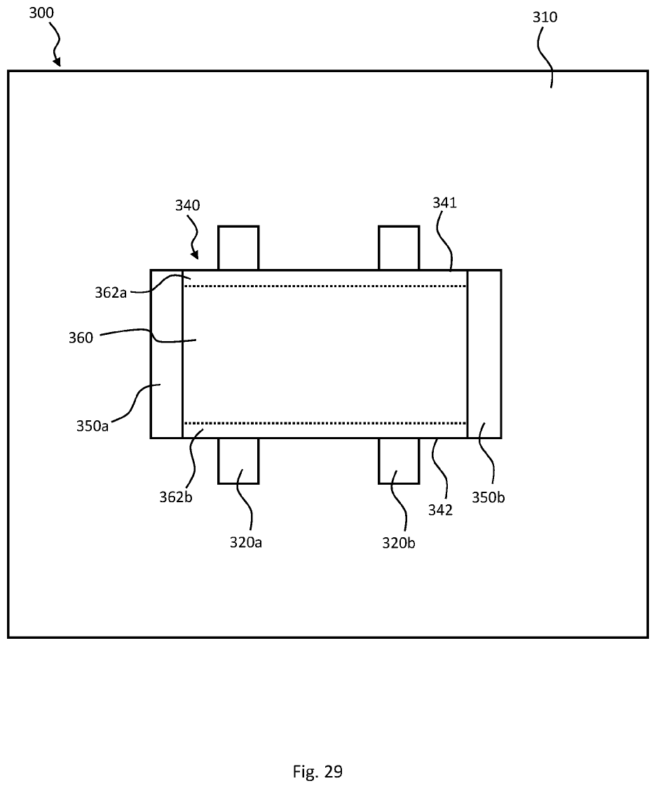

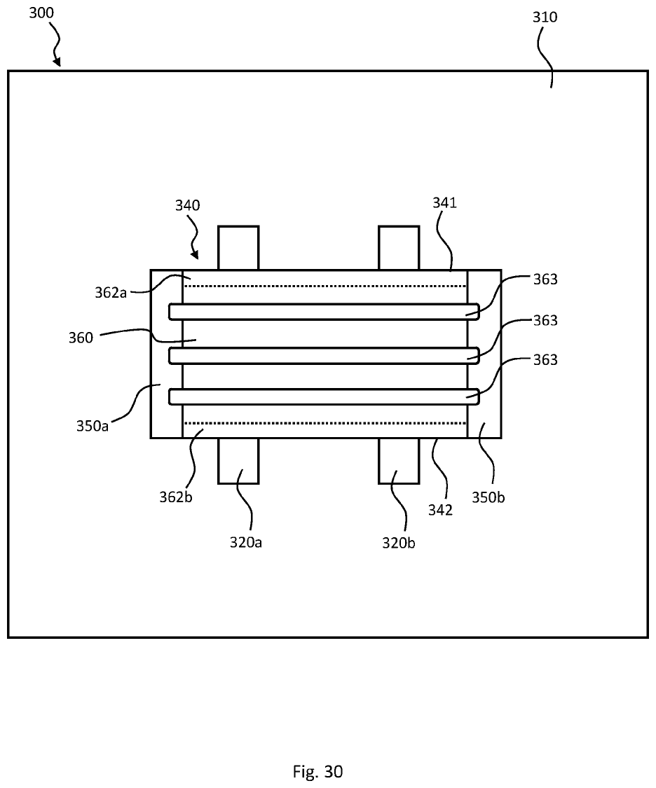

The above examples have shown a shunt embodiment. However, the MEMS bridge is also useful with series embodiments. An example of a series embodiment is shown in FIG. 29 which illustrates a radio frequency, RF, microelectromechanical MEMS, switch 300 according to the present invention from a plan view. In addition, all of the example bridges described above are useful with the series configuration.

The RF MEMS switch 300 comprises a substrate 310 which functions as the base of the RF MEMS switch 300. The RF MEMS switch 300 comprises a first signal conductor 320a and a second signal conductor 320b. The MEMS bridge is indicated generally by reference numeral 340 and comprises a variable capacitor region 360. The variable capacitor region 360 has a first longitudinal edge 341 and a second longitudinal edge 342. The MEMS bridge 340 is connected to the substrate 310 by an anchors 350a, 350b. The variable capacitor region 360 extends over the first signal conductor 320a and the second signal conductor 320b.

FIG. 30 shows the MEMS bridge 340 of a series embodiment of the device with three slots 363 from a plan view. The slots 363 extend further longitudinally than the first and second longitudinal edges 341, 342 of the variable capacitor region 360.

What is claimed is:

1. A radio frequency, RF, microelectromechanical systems, MEMS, switch comprising: a substrate; a first signal conductor on the substrate; ground conductors supported on either side of the first signal conductor on the substrate; and a MEMS bridge at least one end of which is mechanically connected to the substrate by way of at least one anchor, the MEMS bridge comprising a variable capacitor region provided over the first signal conductor, the variable capacitor region comprising a first dielectric layer and a first conductive layer, the first conductive layer positioned on a surface of the first dielectric layer facing the substrate and separated into at least a first longitudinal conductive portion and a second longitudinal conductive portion which are spaced apart in a direction perpendicular to the longitudinal length of the MEMS bridge, wherein the substrate comprises one or more pull-down substrate conductors and the MEMS bridge comprises one or more actuatable conductors located between the anchors and the variable capacitor region and provided above the one or more pull-down substrate conductors, wherein at least one of the one or more actuatable conductors comprises an embedded portion which extends longitudinally along the MEMS bridge and between the first and second longitudinal conductive portions.

2. The RF MEMS switch of claim 1, comprising the embedded portion, wherein the embedded portion extends between the first and second longitudinal conductive portions without contacting them.

3. The RF MEMS switch of claim 1, wherein the embedded portion is provided at least partially over the ground conductors.

4. The RF MEMS switch of claim 1, wherein the first and second longitudinal conductive portions extend along opposing longitudinal edges of the variable capacitor region parallel to the longitudinal length of the MEMS bridge.

5. The RF MEMS switch of claim 1, wherein the first and second longitudinal conductive portions are not in conductive connection with one another and/or wherein the first and second longitudinal conductive portions each extend laterally across the MEMS bridge by less than a third of the lateral width of the MEMS bridge, in the direction perpendicular to the longitudinal length of the MEMS bridge.

6. The RF MEMS switch of claim 1, wherein the first and second longitudinal conductive portions form separate parallel variable capacitive connections between the first signal conductor and the ground conductors, optionally wherein the MEMS switch comprises a second signal conductor and wherein the first and second longitudinal conductive portions form separate parallel variable capacitive connections between the first and second signal conductors, typically having a series configuration and comprising the second signal conductor, wherein the first longitudinal conductive portion forms a first parallel variable capacitive connection comprising a plurality of capacitances and the second longitudinal conductive portion forms second parallel variable capacitive connection comprising a plurality of capacitances, wherein the first parallel variable capacitive connection comprises a first capacitance between the section of the first longitudinal conductive portion provided over the first signal conductor and the first parallel variable capacitive connection comprises a second capacitance between the section of the first longitudinal conductive portion provided over the second signal conductor.

7-8. (canceled)

9. The RF MEMS switch of claim 1, wherein the first conductive layer comprises one or more third longitudinal conductive portions extending parallel to and between the first and second longitudinal conductive portions, optionally wherein the one or more third longitudinal conductive portions each extend laterally across the MEMS bridge by less than 25% of the lateral width of the MEMS bridge, in the direction perpendicular to the longitudinal length of the MEMS bridge.

10. The RF MEMS switch of claim 1, wherein the MEMS bridge comprises one or more slots extending longitudinally along the MEMS bridge and the one or more slots extending through both the first dielectric layer and the first conductive layer, typically wherein the one or more slots extend laterally across the MEMS bridge in total by greater than 20% of the lateral width of the MEMS bridge, in the direction perpendicular to the longitudinal length of the MEMS bridge optionally wherein the one or more slots extend longitudinally further towards a respective end of the MEMS bridge than at least one longitudinal edge of the variable capacitor region.

11. (canceled)

12. The RF MEMS switch of claim 10, wherein the lower surface of the MEMS bridge comprises the first and second longitudinal conductive portions, each longitudinal conductive portion provided along a longitudinal edge of the variable capacitor region, further comprising an alternating patten of a slot and a strip of the first dielectric layer.

13. The RF MEMS switch of claim 1, wherein at least one of the one or more actuatable conductors comprises one or more slots extending longitudinally along a portion of the MEMS bridge and/or wherein the RF MEMS switch comprises one or more dimples between one or more actuatable conductors and the one or more pull-down substrate conductors.

14. (canceled)

15. The RF MEMS switch of claim 1, wherein the MEMS bridge comprises a second dielectric layer provided between the first conductive layer and the signal conductor(s), wherein the second dielectric layer is provided on at least one of: the signal conductor(s) and the first conductive layer.

16. The RF MEMS switch of claim 1, wherein the MEMS bridge is deformable from a first position in which the variable capacitor portion is spaced from the respective signal conductor to a second position in which the variable capacitor region is closer to the respective signal conductor than in the first position by way of an electrostatic actuation force, wherein capacitances between the variable capacitance region and the signal conductor(s) are greater when the MEMS bridge is in the second position than when the MEMS bridge is in the first position.

17. The RF MEMS switch of claim 16, wherein the MEMS bridge comprises a second dielectric layer provided between the first conductive layer and the signal conductor(s), wherein the second dielectric layer is provided on at least one of: the signal conductor(s) and the first conductive layer and wherein the second dielectric layer comprises one or more pads on at least one of: the signal conductor(s) and the ground conductors, wherein the change in capacitances between the first position and the second position is dependent on dimensions of the one or more pads, optionally wherein an electrical permittivity of the one or more pads is greater than a relative permittivity, normalised to air, of 1.

18-19. (canceled)

20. The RF MEMS switch of claim 1, wherein the first and second longitudinal conductive portions extend along the entirety of the longitudinal edges of the variable capacitor region.

21-22. (Cancelled).

23. A method of manufacturing a radio frequency, RF, microelectromechanical systems, MEMS, switch according to claim 1, the method comprising: providing a substrate; providing a first signal conductor supported on the substrate; providing ground conductors supported on either side of the first signal conductor on the substrate; and providing a MEMS bridge comprising a variable capacitor region over the first signal conductor by providing a first dielectric layer and a first conductive layer, the first conductive layer provided on the surface of the first dielectric layer facing the substrate and separated into at least a first longitudinal conductive portion and a second longitudinal conductive portion which are spaced apart in a direction perpendicular to the longitudinal length of the MEMS bridge, the method further comprising providing one or more pull-down substrate conductors and one or more actuatable conductors extending above the one or more pull-down substrate conductors between the anchors and the variable capacitor region, wherein providing the one or more actuatable conductors comprises providing an embedded portion which extends longitudinally along the MEMS bridge and between the first and second longitudinal conductive portions.

24. The method of manufacturing an RF MEMS switch of claim 23, wherein providing the first conductive layer comprises providing the first and second longitudinal conductive portions extending along opposing longitudinal edges of the variable capacitor region parallel to the longitudinal length of the MEMS bridge.

25. The method of manufacturing an RF MEMS switch of claim wherein providing the first conductive layer comprises providing one or more third longitudinal conductive portions extending parallel to and between the first and second longitudinal conductive portions.

26. The method of manufacturing an RF MEMS switch of any of claim 23, comprising providing one or more slots extending longitudinally along the MEMS bridge and extending through both the first dielectric layer and the first conductive layer.

27. A circuit comprising a plurality of radio frequency, RF, microelectromechanical systems, MEMS, switches comprising: a substrate; a signal conductor supported on the substrate; ground conductors supported on the substrate on either side of the signal conductor; and a MEMS bridge at least one end of which is mechanically connected to the substrate by way of at least one anchor, the MEMS bridge comprising a variable capacitor region provided over the signal conductor and the ground conductors, wherein the MEMS bridge is deformable from a first position in which the variable capacitor portion is spaced from the respective signal and ground conductor(s) to a second position in which the variable capacitor region is closer to the respective signal and ground conductor(s) than in the first position by way of an electrostatic actuation force, wherein capacitances between the variable capacitance region and the signal conductor and the ground conductors are greater when the MEMS bridge is in the second position than when the MEMS bridge is in the first position, wherein the variable capacitor region comprises a first dielectric layer and a first conductive layer, the first conductive layer positioned on a surface of the first dielectric layer facing the substrate, the variable capacitor region further comprising a second dielectric layer provided between the first conductive layer and the signal conductor and the ground conductors, wherein the second dielectric layer comprises one or more pads on the signal conductor and the ground conductor, wherein the change in capacitance between the first position and the second position is dependent on dimensions of the one or more pads and wherein the circuit comprises RF MEMS switches comprising different dimensioned one or more pads so the change in capacitance between the first position and the second position of the RF MEMS switches is different.

28. A method of manufacturing a circuit according to claim 27, the method comprising: providing a substrate; providing a signal conductor and ground conductors on either side of the signal conductor supported by the substrate; providing a MEMS bridge comprising a variable capacitor region over the signal conductor and the ground conductors by providing a first dielectric layer, a first conductive layer and a second dielectric layer, the first conductive layer provided on the surface of the first dielectric layer facing the substrate and the second dielectric layer provided between the first conductive layer and the signal conductor and the ground conductors, wherein providing the second dielectric layer comprises providing one or more pads on the signal conductor and the ground conductor and providing the one or pads comprises selecting a change in capacitance between the first position and the second position and selecting dimensions of the one or more pads in dependence on the selected change in capacitance.
